(19) United States
(12) Patent Application Publication
(10) Pub. No.: US 2017/0085235 A1
(43) Pub. Date: Mar. 23, 2017

(54) SINGLE POLE DOUBLE THROW AMPLIFIER

(71) Applicant: AGENCY FOR SCIENCE, TECHNOLOGY AND RESEARCH, Singapore (SG)

(72) Inventors: Xiaojun BI, Singapore (SG); M Annamalai ARASU, Singapore (SG); Minkyu JE, Singapore (SG)

(21) Appl. No.: 15/311,510

(22) PCT Filed: Jun. 10, 2015
(86) PCT No.: PCT/SG2015/050155

§ 371 Date: Nov. 15, 2016

(30) Foreign Application Priority Data
Jun. 10, 2014 (SG) 10201403089Q

(51) Int. Cl. H03F 3/60; H03F 3/217; H03F 3/19; H03F 1/56

(52) U.S. Cl. CPC H03F 3/605; H03F 1/56; H03F 3/217; H03F 3/19; H03F 2200/255; H03F 2200/423; H03F 2200/294; H03F 2200/465; H03F 2200/471; H03F 2200/451; G01R 29/0857

(57) ABSTRACT

A single-pole-double-throw (SPDT) amplifier having two inputs and one output is provided. The SPDT amplifier includes two distributed switchable base lines, each coupled to the two inputs. The SPDT further includes a two stage distributed amplifier connected between the distributed switchable base lines, coupled to the output.

### PRIORITY CLAIM

The present application claims priority to Singapore Patent Application No. 10201403089Q.

### TECHNICAL FIELD

The present invention relates to a switching amplifier. In particular, it relates to a single-pole-double-throw (SPDT) amplifier.

### BACKGROUND ART

The low frequency gain fluctuation of the front-end amplifiers decreases the temperature sensitivity of total power radiometer receivers. The power spectral density (fluctuation spectrum) of radiometers employing semiconductor front-ends follows a 1/f (inversely proportional to frequency) slope at very low frequencies, where the signal of interest lies. A Dicke switch alleviates this problem through modulation of the input signal at a rate significantly higher than 1/f corner frequency, a frequency above which the low frequency gain fluctuations cease to be the main limiting factor for temperature sensitivity. The modulation is realized by using a SPDT switch that connects the radiometer front-end amplifier to the receiving antenna input and a reference resistor alternately.

However, the introduction of the SPDT switch introduces additional passive loss before the Low Noise Amplifier (LNA) or the front-end amplifier, which increases the receiver's equivalent noise temperature (TN) and further result in a larger noise equivalent delta temperature (NEDT).

Thus, what is needed is a “SPDT amplifier” to minimize the passive switching loss preceding the erstwhile front-end amplifier/LNA. Furthermore, other desirable features and characteristics will become apparent from the subsequent detailed description and the appended claims, taken in conjunction with the accompanying drawings and this background of the disclosure.

### SUMMARY OF INVENTION

According to the Detailed Description, a single-pole-double-throw (SPDT) amplifier having two inputs and one output is provided. The SPDT amplifier includes two distributed switchable base lines, each coupled to the two inputs. The SPDT further includes a two stage distributed amplifier connected between the distributed switchable base lines, coupled to the output.

Additionally, in accordance with the detailed description, a method for amplifying an input signal using a distributed switchable base line and a two-stage distributed amplifier is provided. The method includes amplifying a first portion of the input signal by the two-stage distributed amplifier after the input signal passes through a portion of the distributed switchable base lines. The method further includes amplifying a second portion of the input signal by the two-stage distributed amplifier after the input signal passes through additional portion of the distributed switchable base lines.

### BRIEF DESCRIPTION OF DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages in accordance with a present embodiment.

FIG. 1 illustrates Dicke radiometer topology in accordance with an embodiment of the present application.

FIG. 2 depicts SPDT amplifier in accordance with an embodiment of the present application.

FIG. 3 illustrates comparison of the Noise Figure between the SPDT amplifier in accordance with an embodiment of the present application and conventional LNA.

FIG. 4 comprises FIGS. 4(a) and (b). FIG. 4(a) depicts simulated S21 and isolation and FIG. 4(b) depicts Reflection coefficient in accordance with an embodiment of the present application.

FIG. 5 depicts output power VS input power in accordance with an embodiment of the present application.

FIG. 6 depicts the LNA and detector in the receiver in accordance with an embodiment of the present application.

FIG. 7 illustrates simulated noise figure and gain of the receiver in accordance with an embodiment of the present application.

FIG. 8 depicts detector voltage VS input power and square law region of the receiver in accordance with an embodiment of the present application.

Skilled artisans will appreciate that elements in the figures are illustrated for simplicity and clarity and have not necessarily been depicted to scale. For example, the dimensions of some of the elements in the illustrations, block diagrams or flowcharts may be exaggerated in respect to other elements to help to improve understanding of the present embodiments.

### DESCRIPTION OF EMBODIMENTS

The following detailed description is merely exemplary in nature and is not intended to limit the invention or the application and uses of the invention. Furthermore, there is no intention to be bound by any theory presented in the preceding background of the invention or the following detailed description. Herein, a SPDT amplifier is presented in accordance with present embodiments having the advantages of improved noise equivalent delta temperature through a low loss switching preceding the LNA.

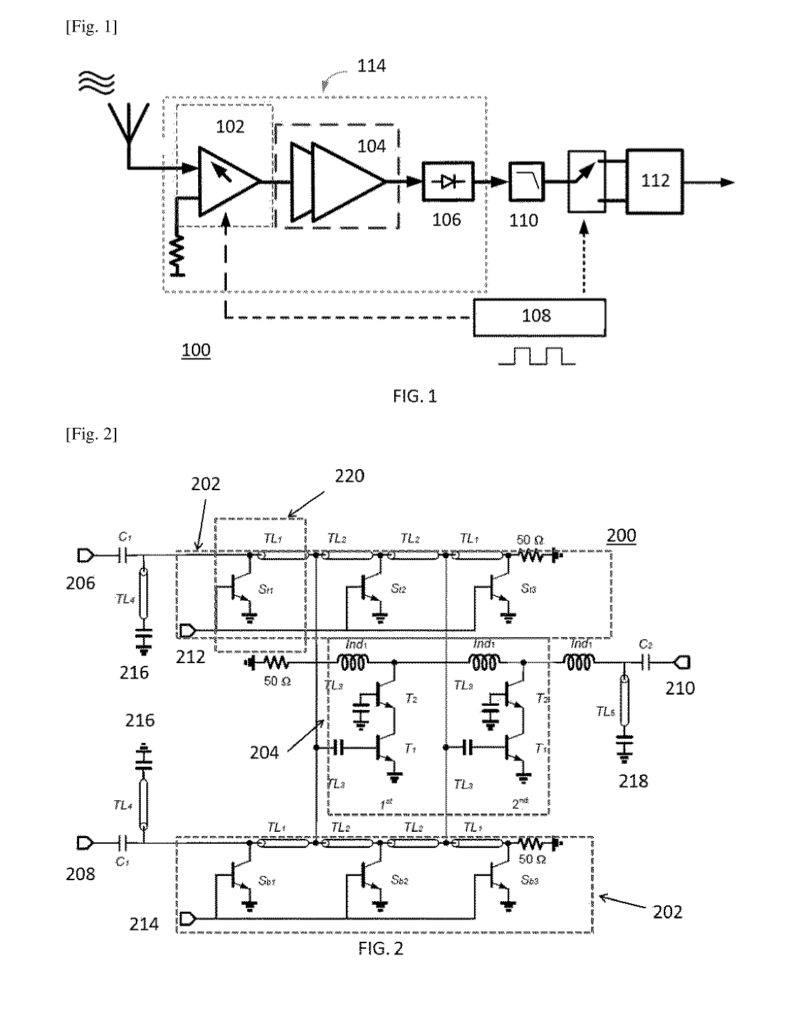

FIG. 1 depicts Dicke radiometer topology 100 in accordance with an embodiment of the present application. A switching amplifier 102, having two inputs and one output, is connected to LNA 104 at the output. The LNA 104 is connected to Power Detector 106. The switching amplifier 102, LNA 104 and Power Detector 106 may be implemented on-chip. Output of the Power Detector 106 is processed by integrator 110 and modulated by Pulse generator 108 and then demodulated by demodulator 112. The Pulse generator 108 also modulate signal at the switching amplifier 102.

In an embodiment of the present application, the switching amplifier 102 is a SPDT amplifier. The SPDT amplifier is proposed to implement the switching function as well as the signal pre-amplification. The SPDT amplifier 102 is followed by a high gain LNA 104. According to the noise figure (NF) calculation in the cascaded systems, the noise figure from the LNA 104 and the following building blocks are mitigated by the gain of the SPDT amplifier 102. Therefore, the receiver's NF is mainly decided by SPDT amplifier noise figure.

FIG. 2 depicts a SPDT amplifier 200 in accordance with an embodiment of the present application. The SPDT amplifier 200 consists of two-stage distributed cascode amplifier 204 and two switchable distributed base lines 202. Through the sizing of T1 and T2 and providing a proper bias current, the NFₘᵢₙ and gain per stage of the distributed cascode amplifier 204 is optimized.

Characteristic impedance is chosen as Zₒ. Ind₁ and equivalent inductance of TL1 can be derived according to base-emitter capacitance and collector-emitter capacitance respectively. The Ind₁ can also be substituted by transmission lines if parasitic capacitance at the collectors is small enough.

Transmission lines TL1 and TL2 can form the base line 202 of the distributed amplifier 204. In the meantime, HBT switches 220 are connected to the base line with an optimum spacing. For instance, the spacing between Sₜ₁ and Sₜ₂ is TL1 plus TL2. First Matching networks 216 and Second Matching networks 218 are added for the two inputs 206, and 208 to obtain the optimum specifications in terms of noise figure and gain over the specified frequency range. In an example, the first matching networks 216 are designed for minimum noise and the second matching network 218 is designed for maximum gain.

The upper switch array consists of Sₜ₁ to Sₜ₃ 220 is controlled by control voltage 212 through base while the bottom array is controlled by control voltage 214. The two control voltages 212 and 214 have the same magnitude and possess a 180 degree phase difference. Using two pulses to turn on and off the two different branches, the input signals at 206 and 208 are amplified periodically. The output port is 210. More specifically, when control voltage 212 is high and control voltage 214 is low, the top branch is turned-off and bottom branch is turned-on. The input signal at 206 is predominantly shorted to ground while the signal at 208 is amplified by the two cascode stages 204.

For the conventional travelling wave switches, the on-state insertion loss is proportional to the stages of the switches:

$${S}_{21} ≅ \frac{2}{2 + {R}_{on} + N ( jω {C}_{off} ) ( 1 + {R}_{on} )}$$

Regarding the conventional distributed SPDT switch in which the input signal have to pass through all the sections in the branch lines, the loss introduced by the passive connections and switching loss are all added to the noise figure of the following LNA block. This proposed SPDT amplifier 200 can be regarded as a distributed SPDT switch 202, 220 integrated with a two-stage distributed amplifier 204 naturally. More specifically, a portion of the input signal 206, 208 is amplified after they pass through the first section (TL₁) of the branch lines while another portion of the input signal is amplified after they pass through more branch line sections (TL₁+2×TL₂). This operation principle is exactly the same as the distributed amplifier. However, the above two lengths are considerably smaller than a quarter wavelength. The passive loss contribution to the NF of the SPDT amplifier 200 is minimized. Compared with the conventional LNA, the minimum NF achieved by this SPDT amplifier 200 is only slightly higher as verified by simulation.

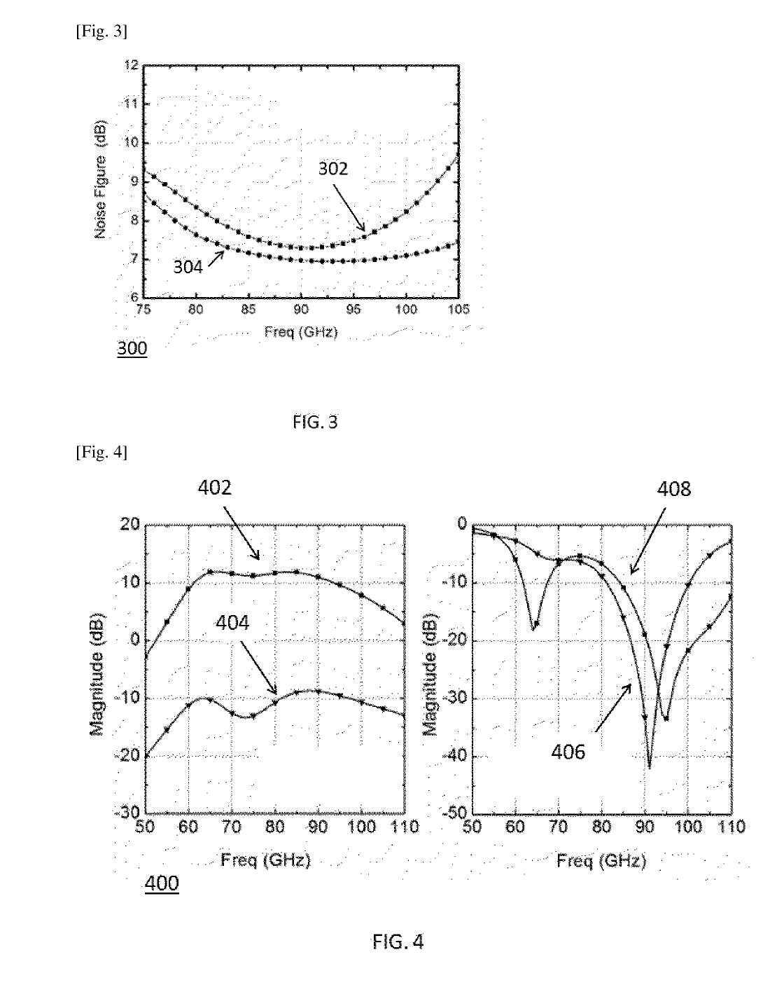

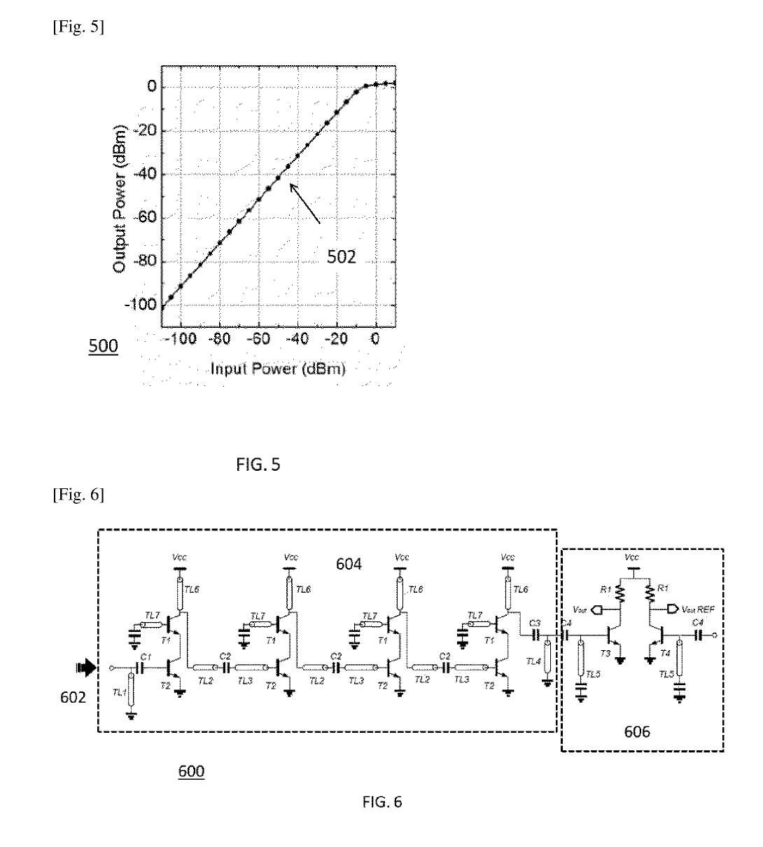

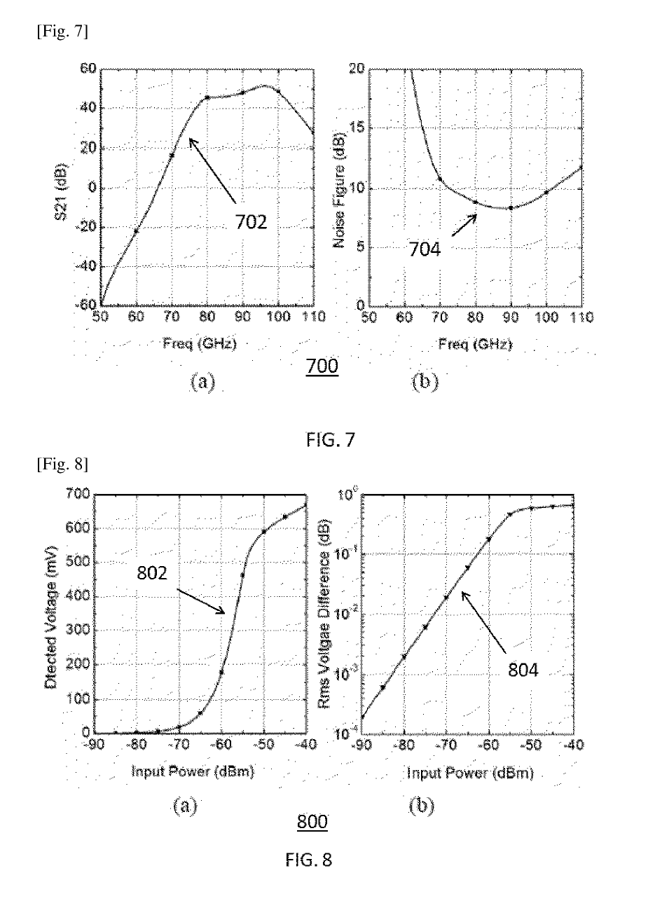

As shown in FIG. 3, the noise figure of the SPDT amplifier 302 is around 7.8 dB at 86 GHz and 7.7 dB at 94 GHz. For the normal cascode stage with a perfect NF matching 304, the NF is around 7.3 dB at 86 GHz and 7.2 dB at 94 GHz (simulated). Therefore, there is <0.5 dB incremental noise figure of this SPDT amplifier compared with typical LNA from 85 to 95 GHz.

Regarding the conventional silicon-based millimeter-wave SPDTs at W-band, the lowest insertion loss are 2.3 dB and 5 dB which can result in a system noise figure above 9.5 dB as shown in table 1. The simulated noise figure of the receiver using a SPDT amplifier 200 followed by LNA 104 is only 8.3 dB. Therefore, the noise figure of the receiver employing a SPDT amplifier 200 can be reduced by 1.2 dB and 3.9 dB at W-band. These insertion loss reductions are extremely difficult to be achieved by passive SPDT fabricated in silicon. In the below comparison table a LNA of 7.2 dB NF is assumed to follow the input passive SPDT or the SPDT amplifier in accordance with the present invention.

In Table 1, link budget for each receiver is listed.

TABLE 1

| | Switching | | Loss of | | | Equivalent |
|---|---|---|---|---|---|---|
| | block | | phase | | | Switching |
| | NF | Gain | shifter | NF of LNA | NF of Rx | Loss |
| Rx of | 7.7 | 8.8 | NA | 7.2 | 8.3 | 1.1 |
| present | | | | | | |
| embodiment | | | | | | |
| Example 1 | 2.3 | −2.3 | NA | 7.2 | 9.5 | 2.3 |
| Example 2 | 5 | −5 | NA | 7.2 | 13.2 | 5 |
| Example 3 | 0.5 | −0.5 | −6 | 7.2 | 10.7 | 3.5 |

Inherent gain of the SPDT amplifier in accordance with an embodiment of the present application can help overcome the noise figure of the following stages. The input signal is split into two parts with a phase difference (before flowing into the two cascade stages) and combined at the collector line after being amplified. Using a T1 and T2 size of 0.12 μm×0.84 μm×4 and biasing current of 2.4 mA, the SPDT amplifier achieves a gain above 8.8 dB at 94 GHz while the other branch shows 10 dB loss as shown in FIG. 4(a). As shown in FIG. 4(b), the S11 and S22 are around −19 dB at 94 GHz and it has a bandwidth from around 80-100 GHz.

The isolation above −23 dB from 50-130 GHz is sufficient for the radiometer. An isolation of >20 dB can provide a sufficient approximation to the square wave modulation for the radiometer. The input 1 dB compression point is around −7 dBm which is sufficient for the passive imaging since the natural emission of objects and human body are usually in pW level.

FIG. 6 demonstrates the remaining two on-chip building blocks of the imaging receiver. It consists of a four-stage cascade LNA and a differential detector. Regarding the receiving part consists of a LNA and a detector, the total noise figure of the receiver is around 8.3 dB and gain is above 35 dB in W-band. For the whole receiver, the output voltage of the detector changes from 20 mV to 650 mV with input power changing from −70 dBm to −40 dBm. NEDT is around 0.24 K with an integration time of 30 ms according to the NEDT definition:

$$NETD = {T}_{N} \sqrt{{( \frac{1}{{B}_{HF} {τ}_{BB}} )}^{2} + {( \frac{Δ G}{{G}_{0}} )}^{2}}$$

where TN is system noise temperature, B_{HF} is the RF bandwidth, T_{BB} is the integration time and ΔG is the gain fluctuation.

Thus, it can be seen that a single-pole-double-throw amplifier and a high sensitivity radiometer firstly using this single-pole-double-throw amplifier for input modulation are provided in accordance with present embodiments. The SPDTA can realize the input modulation and maintain a low switch loss simultaneously. The equivalent switching loss is around 1.1 dB as calculated which is the smallest among all reported radiometers on silicon. This low switching loss can therefore help the radiometer achieved a NEDT as low as 0.24 K which is also the lowest.

In addition, in accordance with the present embodiments, a method for amplifying an input signal realized through the use of distributed switchable base line and a two-stage distributed amplifier have been proposed to modulate input signal and maintain a low switch loss simultaneously. The method includes amplifying a first portion of the input signal by the two-stage distributed amplifier after the input signal passes through a first portion of the distributed switchable base line. The method also includes amplifying a second portion of the input signal by the two-stage distributed amplifier after the input signal passes through additional portion of the distributed switchable base line.

While exemplary embodiments have been presented in the foregoing detailed description of the invention, it should be appreciated that a vast number of variations exist.

It should further be appreciated that the exemplary embodiments are only examples, and are not intended to limit the scope, applicability, operation, or configuration of the invention in any way. Rather, the foregoing detailed description will provide those skilled in the art with a convenient road map for implementing an exemplary embodiment of the invention, it being understood that various changes may be made in the function and arrangement of elements and method of operation described in an exemplary embodiment without departing from the scope of the invention as set forth in the appended claims.

### REFERENCE NUMERALS

100 Dicke radiometer topology
102 Switching Amplifier
104 Low Noise Amplifier (LNA)
106 Power Detector
108 Pulse Generator
110 Integrator
112 Demodulator
114 On-chip part
200 Single-pole-double-throw (SPDT) Amplifier
202 Two Distributed Switchable Base Lines
204 Two Stage Distributed Amplifier
206 Input 1
208 Input 2
210 Output
212 Control Voltage 1
214 Control Voltage 2
216 First Matching Network
218 Second Matching Network
220 Transistor
300 Noise Figure between the SPDT Amplifier and conventional LNA
302 SPDT Amplifier
304 Conventional LNA
400 Simulated S21 and isolation and Reflection coefficient
402 S31
404 S21
406 S11/S22
408 S33
500 Output power VS input power
502 Output power VS input power
600 LNA and detector in receiver
602 input from SPDT Amplifier
604 LNA
606 Detector
700 Simulated noise figure and gain of the receiver
702 S21
704 Noise FIG.
800 Detector voltage VS input power and square law region of the receiver
802 Detector voltage VS input power
804 Root mean square Voltage Difference VS input power

1. A single-pole-double-throw (SPDT) amplifier having two inputs and one output, the SPDT amplifier comprising:
two distributed switchable base lines, each coupled to the two inputs; and
a two stage distributed amplifier connected between the distributed switchable base lines, coupled to the output.

2. The SPDT amplifier in accordance with claim 1, each of the two distributed switchable base lines comprises a transistor switch for switching.

3. The SPDT amplifier in accordance with claim 1, further comprising first matching networks connected to each input of the SPDT amplifier and a second matching network connected to the output of the SPDT amplifier.

4. The SPDT amplifier in accordance with claim 3, wherein the first matching networks are each configured for noise matching.

5. The SPDT amplifier in accordance with claim 3, wherein the second matching network configured for gain matching.

6. A receiver comprising:
a SPDT amplifier having two inputs and one output, the SPDT amplifier comprising:
two distributed switchable base lines, each coupled to the two inputs; and
a two stage distributed amplifier connected between the distributed switchable base lines, coupled to the output;
a plurality of Low Noise Amplifiers (LNAs) coupled to the SPDT amplifier; and
a differential detector coupled to the plurality of LNAs.

7. The receiver in accordance with claim 6, wherein the plurality of LNAs is a cascaded four-stage LNA.

8. The receiver in accordance with claim 6, wherein the receiver is a Dicke radiometer.

9. The receiver in accordance with claim 6, configured to modulate an input signal received at the two inputs and maintain a low switch loss simultaneously.

10. A method for amplifying an input signal using a distributed switchable base line and a two-stage distributed amplifier, comprising:
amplifying a first portion of the input signal by the two-stage distributed amplifier after the input signal passes through a first portion of the distributed switchable base line; and
amplifying a second portion of the input signal by the two-stage distributed amplifier after the input signal passes through additional portion of the distributed switchable base line.
